(19) United States
(12) Patent Application Publication
(10) Pub. No.: US 2010/0216263 A1
(43) Pub. Date: Aug. 26, 2010

(54) Method and Apparatus for Measuring Process Parameters of a Plasma Etch Process

(75) Inventors: Stephen Daniels, Dublin (IE); Shane Glynn, Offaly (IE); Felipe Soberon, Dublin (IE); Maria Tipaka, Dublin (IE)

Correspondence Address: LOZA & LOZA LLP, 305 North Second Ave., #127, Upland, CA, 91786-6064, US

(73) Assignee: LEXAS RESEARCH, LTD., Dublin (IE)

(21) Appl. No.: 12/524,855

(22) PCT Filed: Jan. 31, 2008
(86) PCT No.: PCT/EP2008/051226

§ 371 Date: Jul. 28, 2009

(30) Foreign Application Priority Data
Feb. 2, 2007 (IE) S2007/0064
Apr. 23, 2007 (IE) S2007/0301

(51) Int. Cl. H01L 21/66; H01L 21/465

(52) U.S. Cl. 438/16; 156/345.24; 257/E21.485; 257/E21.529

(57) ABSTRACT

Method and apparatus for measuring process parameters of a plasma etch process. A method for detecting at least one process parameter of a plasma etch process being performed on a semiconductor wafer. The method comprises the steps of detecting light being generated from the plasma during the etch process, filtering the detected light to extract modulated light; and processing the detected modulated light to determine at least one process parameter of the etch process.

### FIELD OF INVENTION

The present invention relates to plasma etch processes. More particularly, the invention relates to a method and an apparatus for determining a number of the process parameters in a plasma etching process on a semiconductor wafer of a particular wafer batch. These process parameters include the wafer etch rate and etch depth, and the endpoint of the etching process.

### BACKGROUND OF THE INVENTION

One of the main processes involved in semiconductor manufacturing is the etching of the semiconductor. A typical etch process requires plasma discharge to remove a patterned layer of exposed material on the semiconductor wafer surface. The wafer may comprise of one or more layers. Where patterned trenches are etched on the Silicon wafer, the process is known as Deep Reactive Ion Etching (DRIE) or Shallow Trench Isolation (STI).

There are a number of etching processes which are in use by the semiconductor industry. Two commonly used etching tools or reactors for the etching process are the Capacitive Coupled Plasma (CCP) tool, and the Transformer Coupled Plasma (TCP) tool.

The principles of the etching process may be explained with reference to FIGS. 1 to 3. FIG. 1 shows a cross sectional view of a typical CCP processing tool. A vacuum chamber 10 incorporates a bottom electrode 2, on which the wafer or substrate 3 is placed, and a top electrode 7. A gas inlet 8 and an exhaust line 9 are also provided. The chamber also includes a bottom electrode radio frequency (RF) power supply 1.

FIG. 2 shows a cross sectional view of a typical TCP processing tool. This processing tool incorporates substantially the same components as the CCP processing tool, but does not include a top electrode. It also includes a second RF power supply 12, an antenna 13 and a dielectric window 6. It is customary to place a matching network (not shown) between the RF power supplies 1 and 12 and the powered electrode/antenna. The purpose of the network is to match the power supply impedance, which is typically 50Ω, to the electrodes/antenna impedance.

Typical operation of such tools is explained with reference to FIG. 3, in relation to a CCP tool. It involves placing a wafer or substrate 3 on the bottom electrode 2, and igniting the plasma by the radio frequency power supply 1 applying a constant amount of energy to the electrode 2 and/or antenna. A constant gas flow of a selection of feedstock gases 11 is also provided, which is pumped at a constant throughput into the chamber.

The etch process results in the removal of material from the wafer 3 by sputtering, chemical etch or reactive ion etch. The removed material is then volatised into the plasma discharge 5. These volatile materials are called etch-by-products 4, and, together with the feedstock gases 11, contribute to the chemistry of the plasma discharge 5. The etch-by-products 4 and the gases 11 are pumped away through the exhaust or pumping port 9. The etch process for a TCP tool operates in a similar fashion.

It will be appreciated that it would be highly desirable to be able to measure the plasma etch or material removal rate, so that the etch feature depth can be determined. This is due to the fact that the depth of the etched patterns is critical for the performance of the electronic devices being constructed from the wafer.

A number of techniques are currently in use to detect the etch rate or etch depth. One such technique described in U.S. Pat. No. 4,367,044 is based on refraction. Other techniques involve the use of diffraction (U.S. Pat. No. 5,337,144), reflectometry (U.S. Pat. No. 6,939,811), and optical emission spectroscopy (OES) (U.S. Pat. No. 4,430,151).

Many of these techniques require complicated set ups to be put in place, such as for example the provision of light sources, optical alignment detectors and space about the plasma etching tool. This of course has the undesirable drawback of adding to the cost of the semiconductor manufacture. Furthermore, the techniques are often based on measurements of certain regions of the wafer, which, in some cases, do not account for the centre to edge variation of the etch depth. Finally, some of these techniques depend on the thickness of the mask which is simultaneously etched. It will be appreciated that these techniques have adverse affects on the accuracy of the depth measurements which are problematic in the semiconductor industry.

It will also be appreciated that it would be very advantageous to be able to detect when the etch process has finished, in order to reduce material costs and to avoid damage to the electronic devices under construction.

In this regard, it has been found that a number of parameters of the etching process change when the etching process is complete. For example, underneath the top layer of the wafer, another layer of a different chemical composition is provided. If this layer is exposed to the same plasma as the first layer, a change in the chemistry of the discharge will result. The change in chemistry is due to the change in the composition of etch by-products coming from the wafer or substrate surface, as a new layer of material is uncovered and begins to be volatised. This chemical change may affect the power, matching network settings, pressure and the plasma optical emission of the etching process.

The etch processing endpoint may therefore be defined as the time period in which there is a change in any, some, or all of the parameters of the etching process which corresponds to the end of the etching of a layer (such as an unmasked top layer), exposing an underneath layer.

To detect the process endpoint, sensors have been used to monitor the time evolution of one or more of these parameters. These parameters may include not only the physical and chemical processes in the discharge and the surface of the processing wafer described above, but also the plasma tool operating conditions. Other parameters which have been found to change during the etching process include radio-frequency power, gas pressure and flow for various gases, and plasma light intensity at various wavelengths (i.e. Optical Emission Spectroscopy (OES)).

FIG. 4 details a graph of an ideal representation of the variation in a process parameter over time during the etch process. It consists of the following five parts:
1. The initial transient (IT) area, when the discharge is turned on.
2. The main etch (ME) area, when the unmasked material on the wafer is continuously etched.
3. The endpoint (EP) area, which is the transition from the main etch to the over-etch. The endpoint begins when the material being etched starts to be cleared from the wafer.
4. The over-etch (OE) area, which is when most or all of the material has been removed from the wafer and the discharge continues etching the following layers. In many cases it is critical to avoid over-etch.
5. The final transient (FT) area, which occurs when the discharge is turned off.

It will be appreciated that for an ideal signal of a parameter of the etching process, the main etch is a continuous process, with the endpoint being identified by a sudden change in the level of the signal. The over-etch of an ideal signal is a uniform process. In an ideal signal, the endpoint is therefore typically seen as a sharp fall in the intensity of the signal. This corresponds to a depletion of the etch-by-products that caused the signal. However, it could also be a rise in the signal, for example possibly due to an increase in other species in the plasma that were initially depleted by the etch-by-products.

As the chemistry of the process is affected by the material being etched on the wafer, one would expect that when the layer is completely removed there would be a simultaneous change in the chemistry of the discharge. However, during a real etching process, it will be appreciated that the wafer may not be etched uniformly over all its area, and this does not follow the ideal representation of FIG. 4. Accordingly, the etched layer may be removed in some areas of the wafer before others. Therefore, in a real signal of a process parameter, the endpoint is not a sharp fall or rise, but a transition from the main etch to the over-etch in a certain amount of time. This is illustrated in FIG. 5, where the real etch signal has a fall endpoint over a period of time Δt. It should also be noted that the parameters may also have a complex time structure associated with various changes through the process, not all of which are associated with the endpoint, e.g. a multi-step etch process. Therefore, the determination of the endpoint must be carefully analysed with the corresponding signal change observed by the tool monitoring sensors.

In some cases, one of the parameters of the etching process is sufficient for use as a process monitor signal for monitoring the endpoint of the plasma process, as it is able to detect a change clearly enough. However, a real signal may also contain a fair amount of noise, and in some cases a drift. A poor signal to noise ratio and/or a strong drift may result in poor sensitivity to endpoint detection algorithms. These are the main problems in low open area situations where only a small fraction of the wafer is etched (1 to 0.5% of the total area). Where this is the case, a number of parameters can be used as process monitor signals. These process monitor signals can then be combined to condense the process evolution into a single monitor signal using multivariate analysis techniques (MVA). MVA techniques are well known in the art, and therefore will not be elaborated further here.

Traditionally, endpoint detection of plasma etch processes has been carried out with the use of optical sensors. Electrical sensors may also be used for endpoint detection. However, as new processes have been developed in the semiconductor manufacturing industry, there has been a drive to achieve a reduction in geometry of the semiconductors. Accordingly, there has been a corresponding need for the development of advanced sensors for process control and process endpoint detection.

In the last few years therefore, optical systems have been further developed to include broadband Optical Emission Spectroscopy (OES) systems, which use multi-wavelength measurements and various algorithms to more accurately determine the occurrence of an endpoint in a process.

A typical optical sensor consists of an array of fast photo-sensitive devices, such as photo-diodes or photo-multipliers. These detect the light emission from the plasma and record them as electrical signals for use as process monitor signals. The sensor may be exposed to light emission from the plasma through view ports in the tool chamber, by placing the sensor against the window, or by using optical fibre light guides between the view port and the sensor. The use of lenses and/or optical filters between the view port and the sensor is optional and may depend on the specific plasma process. Optical filters allow for the detection of light for particular optical wavelength bands. In order to improve the sensor's sensitivity to the process, the optical fibres and the sensor may be preferred in some situations.

As previously discussed, these methods of endpoint detection may measure the time- averaged intensity of one or more spectral lines from the plasma emission. The spectral emission measured is dominated by emissions with long decay times within the bulk plasma, which results in a non-modulated or DC signal. Most systems use a charge coupled device to measure the intensity with an integration time of the order of 10-100 ms. Various univariate and multivariate statistical algorithms can then be implemented to enhance the signal to noise ratio of the endpoint transition. However, these techniques can be unsatisfactory for accurate endpoint detection of plasma etch processes, in particular due to the ever decreasing size of components on semiconductor chips.

U.S. Pat. No. 6,830,939 entitled ‘System and method for determining endpoint in etch processes using partial least squares discriminant analysis in the time domain of optical emission spectra’, shows that chemometric algorithms are increasingly being applied for use in endpoint detection systems.

It will therefore be appreciated that it would be desirable to provide a method and a system which can provide accurate endpoint detection, as well as determine the etch rate and etch depth of the etching process.

### SUMMARY OF THE INVENTION

The present invention, as set out in the appended claims, provides a method for detecting at least one process parameter of a plasma etch process being performed on a semiconductor wafer, the method comprising the steps of:

detecting light being generated from the plasma during the etch process;

filtering the detected light to extract modulated light; and

processing the detected modulated light to determine at least one process parameter of the etch process.

By detecting the modulated light being emitted from the plasma, a very accurate assessment of the process parameters of the etch process can be obtained.

The process parameter may be the endpoint of the etch process.

The process parameter may be the etch rate of the etch process.

The present invention also comprises method for detecting the etch rate of a plasma etch process being performed on a semiconductor wafer, the method comprising the steps of:

detecting light being generated from the plasma during the etch process;

filtering the detected light to extract modulated light; and

processing the detected modulated light to determine the etch rate of the etch process.

By detecting the modulated light being emitted from the plasma, a very accurate assessment of etch rate and etch depth of the etch process can be obtained.

The detecting may further comprises the step of filtering the light to detect selected wavelength bands.

The processing may comprise the steps of:

converting the detected light into a digital signal;

transforming the digital signal into a frequency domain signal;

extracting one or more pre-selected frequencies from the frequency domain signal for use as process monitor signals;

generating a plot proportional to the intensity of the process monitor signals over the elapsed time of the etch process, and determining the etch rate from the plot.

The step of generating a plot proportional to the intensity of the process monitor signals over the elapsed time of the etch process may comprise:

calibrating the values of the process monitor signals so as to generate converted signal values; and

generating a plot of the converted signal values over the elapsed time of the etch process.

Preferably, the step of calibrating comprises the multiplication of a conversion constant to the values of the process monitor signals.

The method may further comprise the step of integrating the plot so as to generate a second plot of etch area over elapsed time of the etch process, and determining the etch depth from the second plot.

The method may further comprise the step of generating an indicator when a signal level transition in the second plot matches a stored value representing a target etch depth.

Suitably, the indicator is a visual or an aural indicator that the target etch depth has been reached.

Preferably, the transforming of the digital signal comprises performing a fast fourier transform on the digital signal.

Preferably, the process monitor signals are determined during a test wafer analysis of wafers of the same batch as the wafer.

Preferably, the conversion constant may be determined during a test wafer analysis of wafers of the same batch as the wafer.

The test wafer analysis of the batch may comprise the steps of:

detecting modulated light being generated from the plasma of a test wafer being etched over the duration of an etch process;

converting the detected modulated light into digital signals;

transforming the digital signals into frequency domain signals;

determining the main frequencies of the frequency domain signals; and

selecting those main frequencies which are sensitive to changes in the etch rate as the process monitor signals.

The step of selecting those main frequencies which are sensitive to changes in the etch rate as the process monitor signals may comprise the step of:

generating electron microscopy images of a set of test wafers over the etching process, measuring the etch rate and etch depth of the etch process as a function of time from the generated images; and

selecting those main frequencies which have values over time which correlate to the measured etch rate and etch depth as the process monitor signals.

Suitably, the method further comprises the step of establishing the linear relationship between the values of the selected process monitor signals over time and the actual etch rate.

Preferably, the established linear relationship is stored as the conversion constant.

The determining the main frequencies comprises the step of determining those frequency domain signals having the higher signal intensity values.

The present invention also comprises a method to determine the process monitor signals and conversion constant for use in a method of detecting the etch rate of a plasma etch process to be performed on a semiconductor wafer from a particular wafer batch, the method comprising the steps of:

placing a test wafer of the wafer batch in a plasma etching tool and initiating the etch process;

detecting modulated light being generated from the plasma of the test wafer over the duration of the etch process;

converting the detected modulated light into digital signals;

transforming the digital signals into frequency domain signals;

determining the main frequencies of the frequency domain signals;

selecting those main frequencies which are sensitive to changes in the etch rate as the process monitor signals;

establishing the linear relationship between the values of the selected process monitor signals over time and the actual etch rate; and

storing the established linear relationship as the conversion constant.

The step of selecting those main frequencies which are sensitive to changes in the etch rate as the process monitor signals may comprise the step of:

generating electron microscopy images of the test wafer,

measuring the etch rate and etch depth of the etch process as a function of time from the generated images; and

selecting those main frequencies which have values over time which correlate to the measured etch rate and etch depth as the process monitor signals.

The determining the main frequencies may comprise the step of determining those frequency domain signals having the higher signal intensity values.

The present invention also provides an apparatus for detecting the etch rate of a plasma etch process being performed on a semiconductor wafer, comprising:

means for detecting light being generated from the plasma during the etch process;

means for filtering the detected light to extract modulated light; and

means for processing the detected modulated light to determine the etch rate of the etch process.

The means for detecting may further comprise a means for filtering the light to detect selected wavelength bands.

The means for processing may comprise:

a means for converting the detected light into a digital signal;

a means for transforming the digital signal into a frequency domain signal;

a means for extracting one or more pre-selected frequencies from the frequency domain signal for use as process monitor signals;

a means for generating a plot proportional to the intensity of the process monitor signals over the elapsed time of the etch process; and

a means for determining the etch rate from the plot.

The means for generating a plot proportional to the intensity of the process monitor signals over the elapsed time of the etch process may comprise:

a means for calibrating the values of the process monitor signals so as to generate converted signal values; and

a means for generating a plot of the converted signal values over the elapsed time of the etch process.

The means for calibrating may comprise a means for multiplication of a conversion constant to the values of the process monitor signals.

The apparatus may further comprise a means of integrating the plot so as to generate a second plot of etch area over elapsed time of the etch process, and a means of determining the etch depth from the second plot.

Preferably, the apparatus further comprises a means of generating an indicator when a signal level transition in the second plot matches a stored value representing a target etch depth.

Preferably, the indicator is a visual or an aural indicator that the target etch depth has been reached.

The means for detecting may be a photo-sensitive device.

The means for transforming may comprise a microcontroller.

The means for transforming may comprise a Field Programmable Gate Array.

The means for extracting one or more pre-selected frequencies from the frequency domain signal for use as process monitor signals and the means for generating a plot proportional to the intensity of the process monitor signals over the elapsed time of the etch process may comprise a computer.

The means of integrating the plot so as to generate a second plot of etch area over elapsed time of the etch process and the means of generating an indicator when a signal level transition in the second plot matches a stored value representing a target etch depth may comprise a computer.

The present invention also provides an apparatus for determining the process monitor signals and conversion constant for use in detecting the etch rate of a plasma etch process to be performed on a semiconductor wafer from a particular wafer batch, comprising:

a plasma etching tool;

a means for detecting modulated light being generated from the plasma of the test wafer over the duration of the etch process;

a means for converting the detected modulated light into digital signals;

a means for transforming the digital signals into frequency domain signals;

a means for determining the main frequencies of the frequency domain signals;

a means for selecting those main frequencies which are sensitive to changes in the etch rate as the process monitor signals;

a means for establishing the linear relationship between the values of the selected process monitor signals over time and the actual etch rate; and

a means for storing the established linear relationship as the conversion constant.

The means for selecting those main frequencies which are sensitive to changes in the etch rate as the process monitor signals comprises:

a means for generating electron microscopy images of the test wafer,

a means for measuring the etch rate and etch depth of the etch process as a function of time from the generated images; and

a means for selecting those main frequencies which have values over time which correlate to the measured etch rate and etch depth as the process monitor signals.

There is also provided a computer program comprising program instructions for causing a computer program to carry out the above method which may be embodied on a record medium, carrier signal or read-only memory.

The present invention also provides a method for detecting the etch rate of a plasma etch process being performed on a semiconductor wafer, the etch process generating a plasma sheath proximate the wafer, the method comprising the step of determining the etch rate using substantially only light emitted from the plasma sheath.

The detected light may include both modulated and non-modulated light.

Preferably, the light emitted from the plasma sheath and the remainder of the plasma are detected together, but the etch rate is determined using substantially only light emitted from the plasma sheath.

The present invention also provides a method for detecting the endpoint of a plasma etch process being performed on a semiconductor wafer, the method comprising the steps of:

detecting light being generated from the plasma;

filtering the detected light to extract modulated light;

processing the detected modulated light to determine when the endpoint of the etch process has been reached; and

generating an indicator when the endpoint has been determined.

The semiconductor wafer typically comprises a plurality of layers, with the etch process involving the removal of portions of a layer. By detecting the modulated light emission, an accurate determination of the etch process endpoint can be achieved, as the modulation of the light will change at the endpoint, for example on transition to the next layer.

The detecting may further comprise the step of filtering the light to detect selected wavelength bands.

The processing may comprise performing an endpoint detection algorithm on the detected modulated light.

The endpoint detection algorithm may comprise the steps of:

converting the detected light into a digital signal;

transforming the digital signal into a frequency domain signal;

determining whether a signal level transition of one or more pre-selected frequencies matches a stored signal level transition value which corresponds to when the endpoint in the etch process is reached.

The step of determining whether a signal level transition of one or more pre-selected frequencies matches a stored signal level transition value may comprise the steps of:

extracting the one or more pre-selected frequencies from the frequency domain signal for use as process monitor signals;

generating a plot of the intensity of the process monitor signals over the elapsed time of the etch process;

and determining whether a signal level transition in the plot matches a stored signal level transition value.

The transforming of the digital signal may comprise performing a fast fourier transform on the digital signal.

The indicator may be a control signal to stop the etch process.

The indicator may be a visual or aural indicator that the etch process is complete.

The stored signal level transition value and the process monitor signals may be determined during a test wafer analysis of wafers of the same batch as the wafer.

The test wafer analysis of the batch may comprise the steps of:

detecting modulated light being generated from the plasma of a test wafer being etched over the duration of the etch process;

converting the detected modulated light signals into digital signals;

transforming the digital signals into frequency domain signals;

determining the main frequencies of the frequency domain signals;

selecting those main frequencies which exhibit a signal level transition when the endpoint of the etch process is reached as the process monitor signals; and

storing the value of this signal level transition for use as the stored signal level transition value.

The step of selecting those main frequencies which exhibit a signal level transition when the endpoint of the etch process is reached as the process monitor signals may comprise the step of generating a plot of the intensity of the main frequencies over the duration of the time of the etch process; and

selecting those main frequencies which exhibit in the plot a signal level transition when the endpoint of the etch process is reached as the process monitor signals.

The present invention also discloses a method to determine the process monitor signals and a signal level transition value for use in a method of detecting the endpoint of a plasma etch process to be performed on a semiconductor wafer from a particular wafer batch, the method comprising the steps of:

placing a test wafer of the wafer batch in a plasma etching tool and initiating the etch process;

detecting modulated light being generated from the plasma of the test wafer over the duration of the etch process;

converting the detected modulated light signals into digital signals;

transforming the digital signals into frequency domain signals;

determining the main frequencies of the frequency domain signals;

generating a plot of the intensity of the main frequencies over the duration of the time of the etch process;

selecting those main frequencies which exhibit in the plot a signal level transition when the endpoint of the etch process is reached as the process monitor signals; and

selecting the value of this signal level transition as the signal level transition value to be stored.

The method may further comprise the step of:

generating electron microscopy images of the test wafer;

and wherein the step of selecting further comprises selecting those main frequencies which exhibit in the plot a signal level transition when the test wafer images show that the endpoint of the etch process is reached as the process monitor signals.

The determining the main frequencies may comprise the step of determining those frequency domain signals having the higher signal intensity values.

The present invention may also comprise an apparatus for detecting the endpoint of a plasma etch process to be performed on a semiconductor wafer, comprising:

a plasma etching tool;

means for detecting light to be generated from the plasma during an etch process;

means for filtering the detected light to extract modulated light;

means for processing the detected modulated light to determine when the endpoint of the etch process has been reached; and

means for generating an indicator when the endpoint has been determined.

The means for detecting may further comprise a means for filtering the light to detect selected wavelength bands.

The means for processing may comprise:

a means for converting the detected light into a digital signal;

a means for transforming the digital signal into a frequency domain signal;

and a means for determining whether a signal level transition of one or more pre-selected frequencies matches a stored signal level transition value which corresponds to when the endpoint in the etch process is reached.

The means for determining whether a signal level transition of one or more pre-selected frequencies matches a stored signal level transition value may comprise:

a means for extracting the one or more pre-selected frequencies from the frequency domain signal for use as process monitor signals;

a means for generating a plot of the intensity of the process monitor signals over the elapsed time of the etch process; and

a means for determining whether a signal level transition in the plot matches a stored signal level transition value.

The means for detecting may be a photo-sensitive device.

The means for transforming may comprise a microcontroller.

The means for transforming may comprise a Field Programmable Gate Array.

The means for extracting the one or more pre-selected frequencies from the frequency domain signal for use as process monitor signals, generating a plot of the intensity of the process monitor signals over the elapsed time of the etch process and

determining whether a signal level transition in the plot matches a stored signal level transition value which corresponds to when the endpoint in the etch process is reached may comprise a computer.

The present invention also provides an apparatus for determining the process monitor signals and the signal level transition value to be stored for use in detecting the endpoint of a plasma etch process to be performed on a semiconductor wafer from a particular wafer batch, comprising:

a plasma etching tool;

a means for detecting modulated light to be generated from the plasma of a test wafer of the wafer batch over the duration of an etch process;

a means for converting the detected modulated light signals into digital signals;

a means for transforming the digital signals into frequency domain signals;

a means for determining the main frequencies of the frequency domain signals;

a means for selecting those main frequencies which exhibit a signal level transition when the endpoint of the etch process is reached as the process monitor signals; and

a means for selecting the value of this signal level transition as the signal level transition value.

The means for selecting those main frequencies which exhibit a signal level transition when the endpoint of the etch process is reached as the process monitor signals may comprise a means of generating a plot of the intensity of the main frequencies over the duration of the time of the etch process; and

a means of selecting those main frequencies which exhibit in the plot a signal level transition when the endpoint of the etch process is reached as the process monitor signals.

There is also provided a computer program comprising program instructions for causing a computer program to carry out the above method which may be embodied on a record medium, carrier signal or read-only memory.

The present invention also provides a method for detecting the endpoint of a plasma etch process being

performed on a semiconductor wafer, the etch process generating a plasma sheath proximate the wafer, the method comprising the step of determining an endpoint using substantially only light emitted from the plasma sheath.

The light emitted from the plasma

sheath and the remainder of the plasma may be detected together, but the endpoint is determined using substantially only light emitted from the plasma sheath.

The detected light may include both modulated light and non-modulated light.

### BRIEF DESCRIPTION OF THE DRAWINGS

The invention will be more clearly understood from the following description of an embodiment thereof, given by way of example only, with reference to the accompanying drawings, in which:

FIG. 1 is a cross sectional view of typical CCP processing tool;

FIG. 2 is a cross sectional view of a typical TCP processing tool;

FIG. 3 is a cross sectional view of the CCP processing tool of FIG. 1 detailing the etch by-products;

FIG. 4 is an ideal graph of the variation in a process parameter over time during the etch process;

FIG. 5 is a real graph of the variation in a process parameter over time during the etch process;

FIG. 6 is a diagram of one embodiment of the components involved in the implementation of the present invention;

FIG. 7 details the process flow of one embodiment of the present invention;

FIG. 8 details further steps of the process flow of FIG. 5 for determining the etch rate and depth;

FIG. 9 details further steps of the process flow of FIG. 5 for determining the endpoint of the etch process;

FIG. 10a details an exemplary etch rate plot of the present invention;

FIG. 10b details an exemplary etch depth plot of the present invention;

FIG. 11 details the process flow of the first steps in determining the optimum process monitor signals for a particular wafer batch;

FIG. 12 shows an example voltage waveform generated from the detection of modulated light;

FIG. 13 shows the FFT waveform generated from applying the FFT to the waveform of FIG. 12;

FIG. 14 details the process flow of further steps in determining th optimum process monitor signals for a particular wafer batch; and

FIG. 15 shows an example of a time process signal from one of the many frequencies in the FFT recorded in a plasma tool.

### DETAILED DESCRIPTION OF THE INVENTION

The present invention provides a method for monitoring a plasma reactor during a wafer etch process with a sensor which is sensitive to the modulation intensity of the radiation emitted from the plasma during the etch process. The data collected by the sensor can then be used to detect the etch rate and etch depth of the wafer being etched, and to determine the endpoint of the wafer etching process.

In order to understand the principles behind the present invention, the chemical reactions which occur during the etch process should be appreciated. During the etching of a wafer, modulated light of a certain amplitude is emitted by the plasma. The amplitude of the modulated light is related to the etch rate. Furthermore, a transition will occur in the concentration of by-products from the etch process as the endpoint is reached. This by-products concentration change will result in a transition in the optical emission from the plasma.

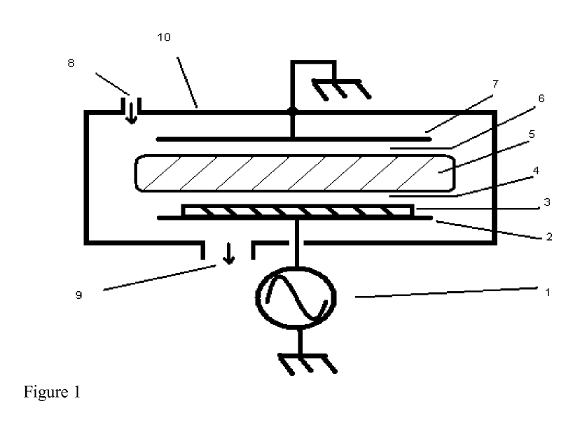

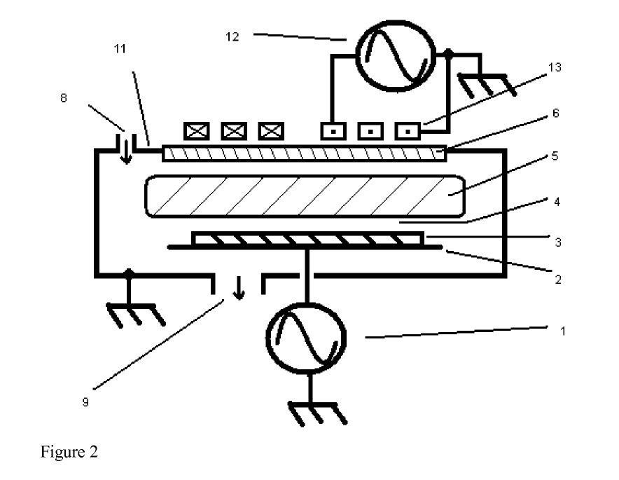

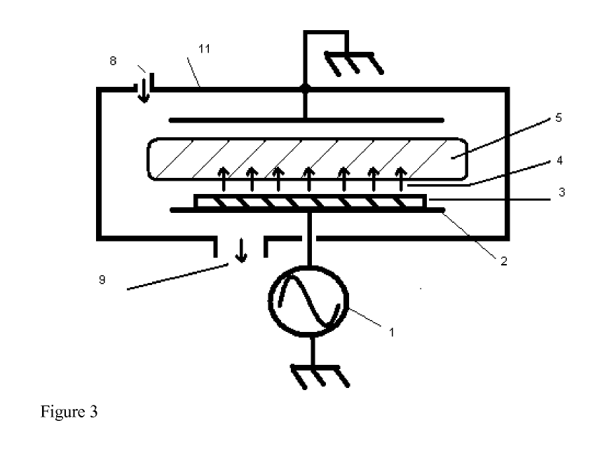

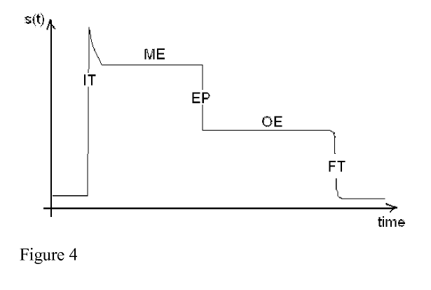

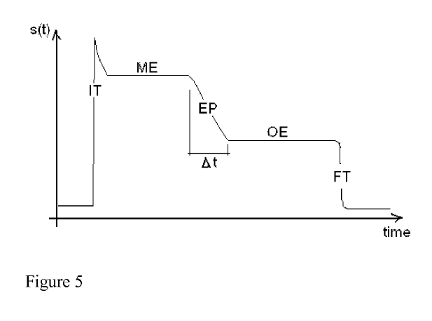

One of the main sources for excitation of atoms or molecules in the discharge is electron impact excitation. These excitations are directly proportional to the electron density. The excitation of atoms and molecules is time uniform in the plasma bulk, where the electron density is time uniform. On the other hand, the electron density in the plasma sheaths, i.e. the region between the plasma and the electrode/wafer, as indicated by 4 in FIGS. 1 to 3, is highly modulated at the driving radio frequency of the etch tool.

The excited species emit light via spontaneous emission with a characteristic decay rate. The excited species can also emit radiation through stimulated emission from the radio frequency cycle. In general, the plasma emission is directly proportional to the number density of species in an excited state. If the density of the species in excited states is modulated, it is expected that the light emission will be modulated in a similar fashion. This gives rise to a non-modulated or DC emission component, together with an additional component, which is modulated at the driving radio-frequency. The modulated light is that light which exhibits a periodic temporal intensity variation at a particular frequency.

Etch by-products resident near the wafer surface are more likely to be excited by the electrons, as the local by-product density is higher in the plasma sheath region. Since the electrons are strongly modulated in the plasma sheath regions, the light from these regions will be highly modulated and the modulation will be correlated with the driving radio frequency.

Due to the fact that the modulated light emission corresponds to light emitted significantly by excited etch-by products at “the sheath” region above the wafer or substrate, it will be appreciated that any variation in the speed at which material is being removed from the surface of the wafer (which corresponds to a change in the etch rate) will be also seen as a change in the modulated light emissions. Therefore, the modulated light is ideal for use in etch rate and depth monitoring.

It has also been found that the modulated light emission is more sensitive to endpoint, as it is independent of memory effects from species with long de-excitation times, such as gases desorbing from the walls and tool drifts, and, because it corresponds to light emitted significantly by excited etch-by products. Therefore, modulated light is also ideal for use in the detection of the etch process endpoint.

In a single frequency etching tool, it is expected that the modulated light will correspond to the driving radio frequency and harmonics. But in dual frequency systems, it is probable to find light modulated at the mixed up products of the two driving frequencies, as well as at the radio frequencies themselves and their harmonics.

The optical sensor of the present invention detects this plasma light modulation. The detected plasma light modulation is then used in order to determine the etch rate, the etch depth, and the etch process endpoint. As the modulated light is substantially in the plasma sheath, the invention therefore involves determining the etch rate, the etch depth and the etch process endpoint by using substantially only light emitted from the plasma sheath.

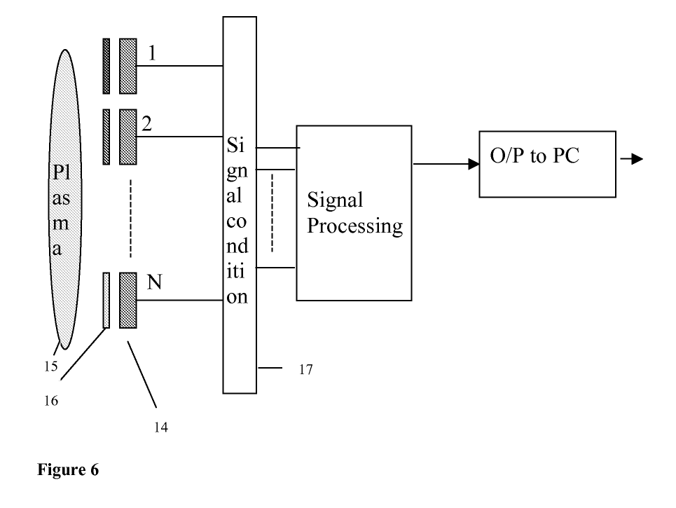

FIG. 6 shows a diagram of one embodiment of the components involved in the implementation of the present invention. A plurality of sensors 14 provide for the detection of plasma light from the plasma 15 located in the etching tool (etching tool not shown). The sensors 14 can take the form of photo-diodes or photo multiplier tubes. In order to successfully detect the plasma light modulation, the sensors should have fast response times. A plurality of optical filters 16 may be used in conjunction with the sensors 14, each filter adapted to detect a particular optical wavelength band, the filters located between the sensors and the plasma. The optical filters have the effect of narrowing the input light to the sensor to bands a few nanometres wide centred at specific wavelengths, so as to select light from certain species in the plasma, such as for example reactants or etch-by-products. This has the effect of removing unwanted wavelength bands. The filters therefore allow the real time monitoring of specific optical lines, enabling the classification of plasma chemistry at the sheath.

A signal conditioning block 17 receives the output data from the sensors 14. At the signal conditioning block 17, the detected light signals from the sensors 14 are conditioned and digitised. In one embodiment of the invention, the conditioning is carried out by a transimpedance amplifier and a programmable voltage amplifier. The transimpedance amplifier converts the signals from the sensors to voltage signals, while the voltage amplifier amplifies these voltage signals. The amplified voltage signals are digitised by an analog to digital converter (ADC). In a preferred embodiment of the invention, the ADC operates at frequencies up to 70 MHz. A processor 18 provides for the processing of the digital signals into the format required in order to enable the etch rate, depth and endpoint to be estimated by the computer (PC) 19. The processor may be any suitable processing device, such as a micro-controller or a Field Programmable Gate Array (FPGA). The computer 19 provides for the further processing of the processor output signal to determine the etch rate, depth and endpoint of the etching process, and to generate one or more indicators when a preset etch depth is reached and the endpoint has been determined.

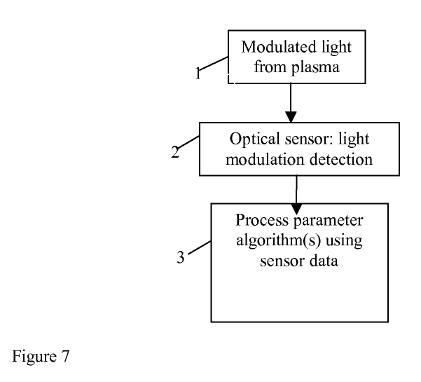

FIG. 7 details the process flow of one embodiment of the present invention. In step 1, light is generated from the plasma of a wafer of a particular batch which is being etched in an etching tool. The optical sensors continuously detect the modulated light emitted from the plasma sheath and the non-modulated light from the remainder of the plasma (step 2). The light may be additionally filtered to only detect light of particular optical wavelength bands. In step 3, the detected plasma light modulation signals are processed in real time to determine at least one process parameter of the etch process. The signals may be processed by an etch rate and depth algorithm. This algorithm determines the etch rate and when a desired etch depth has been reached. An indicator is then generated when the depth has been reached. The plasma light modulation signals may also processed in real time by an endpoint detection algorithm, to determine when the endpoint of the etch process has been reached, and generate an indicator when the endpoint has been determined.

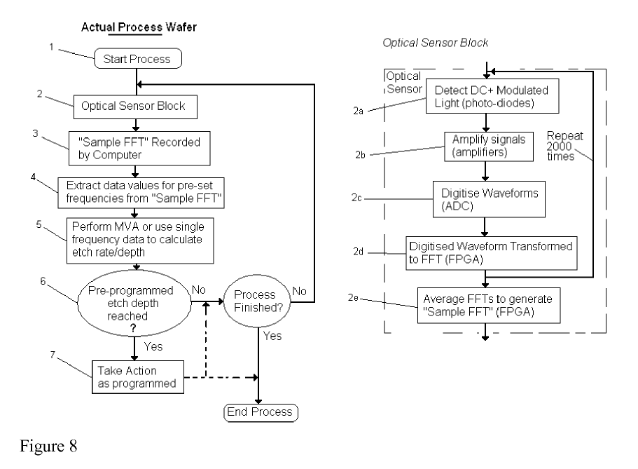

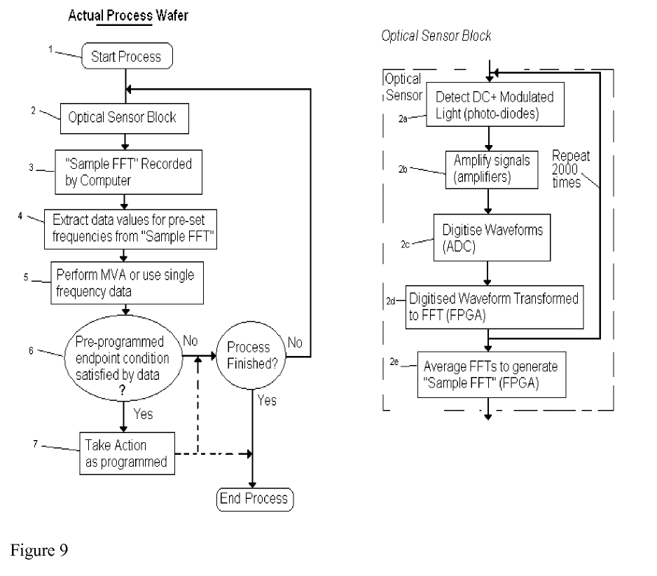

The process flow can be broken down into a number of further steps, which are described in more detail below in relation to FIGS. 8 and 9. FIG. 8 details the steps for determining the etch rate and depth, while FIG. 9 details the steps for determining the endpoint. It should be noted that steps 1 to 4 are identical in both Figures.

Referring to FIG. 8, the etch process is started in step 1. In step 2a, the modulated plasma light of different optical wavelength bands is detected by the optical sensors. The non-modulated light may also be detected. The light is converted to a voltage signal by the transimpedance amplifier, and then subsequently amplified by the voltage amplifier (step 2b). The amplified voltage signal is then digitised by the ADC to provide a digital signal (step 2c). A Fast Fourier transform filter in the processor transforms the digital signal into the frequency domain by calculating a FFT of the digital signal (step 2d).

Steps 2a to 2d are repeated approximately two thousand times, and the resulting set of FFTs averaged to generate a sample FFT (step 2e). It should be noted that the entire averaging process only takes about 250 ms. This sample FFT is recorded by the computer (step 3).

In step 4, the data values of the one or more frequencies of the sample FFT which have been pre-selected to act as process monitor signals are extracted. These process monitor signals have been selected to be those signals which will provide the most accurate assessment of the process parameters which are to be determined, i.e. the etch rate and depth of the etching process and/or of when the endpoint is reached. The selection of the process monitor signals is carried out during test wafer analysis, details of which will be described later. It is therefore through the monitoring of the data values of these process monitor signals that the etch rate may be evaluated, and by which a determination may be made as to whether the required etch depth and endpoint in the etching process has been reached.

It will be appreciated that the above described steps have provided for the filtering of the detected light to extract modulated light from the plasma light, which could have included both modulated and non-modulated light, and the subsequent monitoring of pre-selected modulated light signals in order to determine the etch rate, etch depth and/or the endpoint of the etching process.

The data values for the one or more frequencies which have been extracted from sample FFT values which have already been generated over the elapsed time of the etch process are used to calculate the etch rate and depth, and/or to determine the etch endpoint, as is described below.

For ease of understanding, the further process steps involved where the etch rate and depth is to be determined will first be described, and then the further process steps involved when the end point of the etch process is to be determined is described.

1. Process Steps for Determining the Etch Rate and Etch Depth

To determine the etch rate where a single frequency has being selected as a process monitor signal, the data values which have been extracted from sample FFT values must first be calibrated. This calibration involves the multiplication of a conversion constant to each data value, in order to generate a converted signal value, which, when plotted over the time of the etch process, provides the actual etch rate of the etching process. The conversion constant represents the relationship between the process monitor signal and the actual etch rate.

The correlation between the values of the process monitor signal and the actual etch rate is established during test wafer analysis which has previously been carried out, and the conversion constant is then stored in the computer. This process is described later.

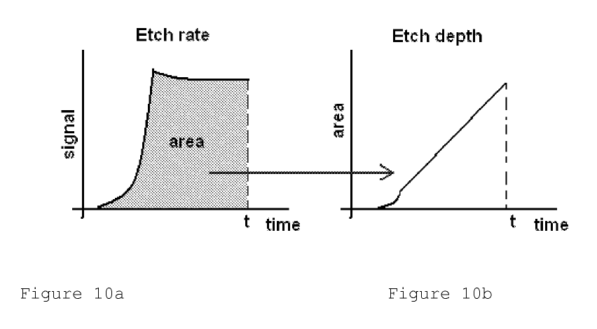

Once the conversion is performed, a plot of the converted process monitor signal versus time is generated in real time, as shown in FIG. 10a. This plot corresponds to the etch rate of the etching process. Therefore the etch rate of the etch process can be determined from this plot (step 5).

Where there is more than one frequency selected as a process monitor signal, the time evolution proportional to the intensity of the various frequency components may be combined as a single plot, using multivariate analysis (MVA) techniques.

It should be noted that the process monitor signals will remain constant where the plasma is removing the wafer material continuously during the etch process, and at a constant rate. It will be appreciated that when the process monitor signals remain constant, there will be a linear relationship between the area and time.

The area underneath the plot of FIG. 10a is directly proportional to the etch depth. Therefore, in order to determine the etch depth, an evaluation of the area underneath the plot is required to be performed. In step 6, a numerical integration of the etch rate signal is carried out in order to calculate the current etch depth. FIG. 10b shows a graphical representation of the etch depth calculation. Therefore the etch depth can be determined from the plot of FIG. 10b.

The plot of FIG. 10b is then analysed to determine whether the target etch depth has been reached for the etch process. In one embodiment of the invention, this is achieved by determining whether a signal level transition on the etch depth plot matches a stored signal level value which represents the target etch depth. The target etch depth is a requirement of the process for the particular semiconductor device in production, and is typically specified by the original designer of the process.

If the signal level transition matches the target value for the etch depth, the process moves to step 7. If a match is not found, the process flow returns to step 2, provided that the etch process has not already been completed.

In step 7, an indicator is generated by the computer that the target etch depth in the etch process has been reached. In one embodiment of the invention, the indicator generated by the computer is a visual or aural indicator. In another embodiment of the invention, the indicator is a control signal for the etching tool to stop the etch process.

It will be understood that the processor could perform a number of alternative tasks once the required etch depth has been reached, depending on a user's requirements for the etch process.

Other numerical techniques could equally well be used instead of Fourier analysis to determine the etch rate/depth.

2. Process for Determining the Endpoint of the Etch Process

Referring now to FIG. 9, to determine the endpoint where a single frequency has being selected as a process monitor signal, a plot of its corresponding intensity as a function of time is generated in real time based on the data values for that frequency extracted from the sample FFT values which have already been generated over the elapsed time of the etch process. Where there is more than one frequency selected as a process monitor signal, the time evolution of the intensity of the various frequency components may be combined as a single plot (step 5).

In step 6, the plot is analysed to determine whether the endpoint condition of the etch process has been satisfied. In one embodiment of the invention, this is achieved by determining whether a signal level transition in the plot matches a stored signal level transition value which corresponds to when the endpoint in the etch process has been reached for the selected process monitor signals of the wafer batch. This stored signal level transition value was determined during test wafer analysis and then pre-programmed into the computer, and will be described in detail later. If a match is found, the process moves to step 7. If a match is not found, the process flow returns to step 2, provided that the etch process has not already been completed.

In step 7, an indicator is generated by the computer that the endpoint in the etch process has been detected. In one embodiment of the invention, the indicator generated by the computer is a visual or aural indicator. In another embodiment of the invention, the indicator is a control signal for the etching tool to stop the etch process.

It will be understood that that the processor could perform a number of alternative tasks once the endpoint has been detected, depending on a user's requirements for the etch process.

Other numerical techniques could equally well be used instead of Fourier analysis to determine when the endpoint is reached.

It will be appreciated that other methods could also be used to determine the endpoint from the selected process monitor signals. For example, pattern recognition techniques could be used to compare the plot of the selected process monitor signals with a stored characteristic plot.

As explained in the background to the invention section, in order to be able to accurately detect process parameters of a particular wafer, it is necessary to first select the most suitable process monitor signals for monitoring the one or more process parameters desired to be determined. In the case of the present invention, this involves determining which of the frequencies of the modulated light are most suitable to act as monitor signals. In reality, each wafer batch has its own unique characteristics. Accordingly, prior to being able to determine the etch rate, depth and/or endpoint of the etch process for wafers of a particular wafer batch, it is necessary to carry out advance preparation, by performing an analysis of each individual wafer batch, to select the most appropriate frequencies which should be monitored in order to enable the etch rate, depth and/or endpoint to be determined for wafers from that particular batch. This is carried out through test wafer analysis of the batch. Furthermore, where there is more than one layer, the values of the process monitor signals for each layer may not necessarily be the same, as every layer produces different etch by products, which affect the discharge in different ways. Accordingly, the test wafer analysis needs to be carried out for each wafer layer.

The process of selecting the optimum process monitor signals is described below using an implementation performed through Fourier analysis. However, as previously advised, it should be appreciated that a number of other numerical techniques could equally well be used instead of Fourier analysis.

The first few steps to determine the optimum process monitor signals are identical to those performed during the etch rate and depth, and the endpoint monitor techniques described above. However, for ease of understanding, they are briefly described below again.

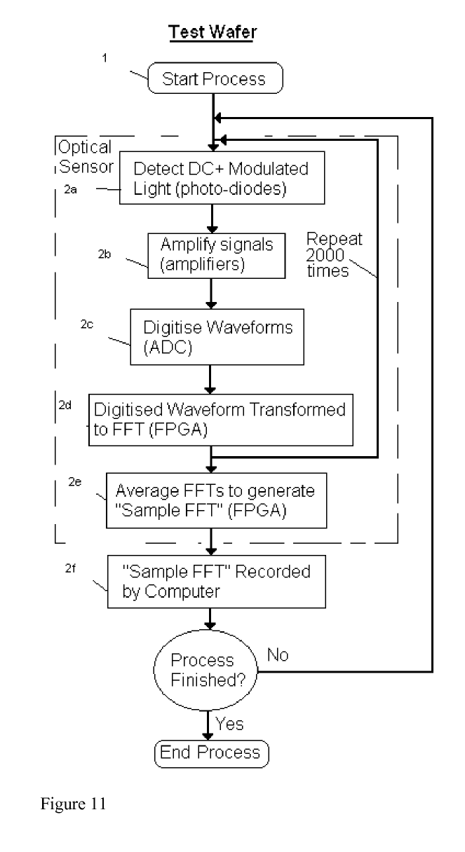

FIG. 11 details the process flow of determining the optimum process monitor signals for a particular wafer batch. In step 1, a test wafer of the batch is placed in the etching tool and the etching process begun. In step 2a, light from the plasma is detected by the sensors, and the light signal is converted to a voltage signal. This light may include both modulated and non-modulated components. The voltage signal is then amplified (step 2b). In step 2c, the voltage signal is digitised and input to the processor. The processor transforms the digitised voltage signal into the frequency domain using the Fast Fourier Transform to provide a FFT (step 2d).

Steps 2a to 2d are repeated approximately two thousand times, and the resulting set of FFT averaged to generate a sample FFT (step 2e), which is recorded by the computer (step 2f). It should be noted that the entire averaging process only takes about 250 ms.

Steps 2a to 2f are repeated over time until the etch process is complete. At this stage, the processor will have recorded a set of sample FFT covering the duration of the entire etch process of the test wafer. Once the process is complete, the generated sample FFT waveform is ready to be examined to determine the optimum frequencies for use as process monitor signals for monitoring the etch rate, depth and/or endpoint for that particular wafer batch.

The first step in the selection of the optimum frequencies of modulated light for use as process monitor signals in respect of all of the wafers of the batch involves the determination of the main frequency components of the sampled FFT.

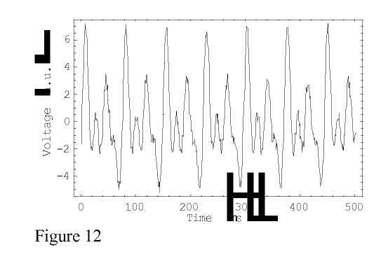

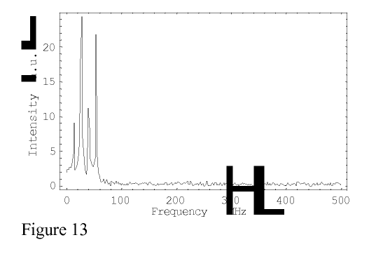

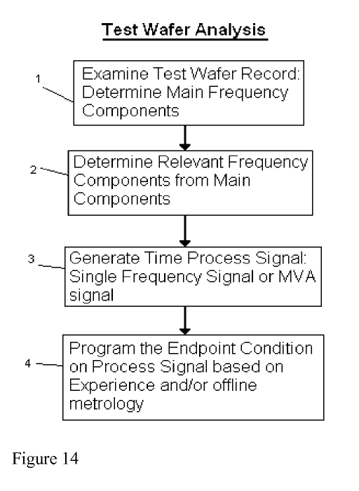

FIGS. 12 and 13 describe how the main frequency components can be determined. FIG. 12 shows an example voltage waveform generated from the detection of modulated light. It will be appreciated that this waveform contains more than one frequency plus noise. FIG. 13 shows the FFT waveform generated from applying the FFT to this voltage waveform. This is a plot of intensity versus frequency. In this example it can be clearly seen that there are four peaks, each below 100 MHz. These peaks indicate the frequency signals that are contained in the waveform, with the height of the peaks indicating the relative intensity of their corresponding frequencies in the waveform. It will be appreciated therefore that the main frequency components correspond to the peaks in the sampled FFT waveform i.e. those frequency domain signals having higher signal intensity values.

As shown in FIG. 12, where the endpoint is to be determined, the main frequency components should be examined (step 1). Those frequency components which exhibit a signal level transition when test wafer images show that the endpoint has been reached should then be determined (step 2). These frequency components are then used as the process monitor signals (step 3) which need to be programmed into the computer (step 4).

Where the etch rate and etch depth are to be determined, once the main frequency components are established, those frequencies from the main frequency components which have a time signal which satisfies two conditions must also be found. The first condition is that the time signal is steady. The first condition is based on the knowledge that the etch rate should be constant. The second condition is that the time signal is sensitive to small etch rate changes. The second condition is imposed to ensure that the one or more process monitor signals are truly correlated to the etch rate.

In general, it can be assumed that the etch rate through each individual layer (in the case where there is more than one layer present) is approximately constant. While etching a layer, minor variations in the etch rate may occur, as the etch rate is not perfectly constant throughout the process. Small changes in the etch rate may also be caused by small drifts in the etching process. However, large variations in the etch rate are more likely associated with etching layer transitions (endpoint) or variations in the process control parameters; such as for example changes in power, pressure, gas flow or mixture.

The second condition is tested by analysing test wafer images in conjunction with the values obtained for the main frequency components, and determining which of the main frequencies over the time of the etch process exhibit values which most closely correlate to the actual etch rate determined from the test wafer images, as explained below.

The test wafer images may be obtained using any of the techniques known in the art. One such technique involves placing a first test wafer in the etching tool and running the etch process until a predetermined time period has elapsed. The test wafer is then removed from the etching tool and the state of its surface examined by slicing the wafer. A second test wafer is then placed in the etch tool, and the etch process run until a second predetermined time period has elapsed, with the second time period being greater than the first time period (which is typically a few seconds more than the first time period). The second test wafer is then removed and its surface examined. This process is repeated on further test wafers from a set of test wafers from the batch, each wafer from the set being of the same quality and possessing the same characteristics, until the predetermined time period exceeds the time taken for the etch depth and/or endpoint to be reached for that particular wafer batch. This process can be repeated for several batches of wafers of same quality and characteristics, with the testing operation run on every batch with small changes in the tool operating parameters.

Once all of the test wafers from the set have been placed in the etching tool, Scanning Electron Microscopy (SEM) images for every single wafer are generated. Other imaging techniques could also be used, such as for example an Atomic Force Microscopy (AFM) technique. The images reveal the time evolution of the process. It will be appreciated that although technically it is not the time evolution of the process of a single wafer, it is accepted that the results should reflect the time evolution of a single wafer, given that the set of wafers have all been prepared in a similar fashion prior to the processing. From the SEM images, it is possible to measure the etch rate and depth and/or process endpoint as a function of time.

These test wafer images permit the calculation of the etch rate and depth as a function of time, and/or the process endpoint. The time signals for the main frequencies detected by the optical sensor that have values which best correlate to the test wafer results for etch rate and depth, and/or process endpoint are then selected for use as the process monitor signals.

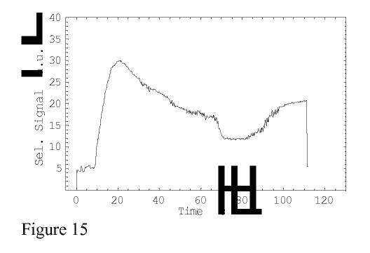

It will of course be appreciated that if a frequency signal does not change at all over the etch process, then it is of no use for the endpoint detection. However, on the other hand, a signal may exhibit many changes throughout the process. FIG. 15 shows an example of a time process signal from one of many frequencies in the FFT recorded in a plasma tool. The etch endpoint in this case has been found to correspond to the signal level transition between 85 and 100 seconds.

Accordingly, a process engineer's knowledge is preferably used in conjunction with the test wafer analysis to determine which signal level transition actually corresponds to that which occurs when the endpoint is reached.

When a single frequency signal is selected as a process monitor signal, the process monitoring is based on this single signal. Alternatively, if more than one frequency is selected as process monitor signals, then the signals can be combined using Multi-Variate Analysis techniques (MVA) to output a single combined time process signal to be used to determine the etch rate and depth, and/or the process endpoint. A typical MVA technique that may be used here is Principal Component Analysis (PCA).

In the final step in the test wafer analysis process, the computer must be programmed with various values in order to enable the at least one process parameter to be determined for a particular wafer undergoing the etch process.

Where the etch rate and depth are to be determined, those frequencies selected to act as process monitor signals for the etch rate must be calibrated. This calibration consists of determining a value for a conversion constant between the actual etch rate (estimated from the wafer analysis) and the frequencies selected to act as process monitor signals over the course of the etch process. This involves establishing the linear relationship between the values of the selected frequency or MVA signal, in the case of more than one useful frequency, over time and the actual etch rate. This is calculated by dividing the measured etch rate (after wafer analysis) by the signal value of the selected frequencies. This constant therefore converts the signal value (in arbitrary units) to the actual etch rate (typically micron/min). Once the relationship is determined, this conversion constant is recorded. This constant is required, as previously explained, in order to convert the values which will be obtained from the process monitor signals over time when the technique of determining the etch rate of the present invention is being carried out, so as to represent the actual etch rate. It should be noted that this constant is particular to a given wafer batch process, and will not convert correctly the signal to the etch rate if the quality or characteristics of the wafer or the process parameters are varied.

The computer must also be programmed with the recorded conversion constant.

Furthermore, the computer must also be programmed with a target etch depth value. This value is that value desired for the depth of the etch on the wafer layer, and is set by the process designer in view of the semiconductor device which is being manufactured on a particular wafer.

Where the endpoint of the etch process is desired to be determined, the computer must be pre-programmed with the value of the signal level transition recorded during the test wafer analysis to correspond to when the endpoint in the etch process is reached for the one or more selected frequencies.

Finally, the computer is programmed to monitor the selected one or more frequencies determined during the test wafer analysis to act as process monitor signals.

As previously noted, where the etching process is to be carried out on more than one layer, the values obtained for the process monitor signals for each layer may not necessarily be the same. Accordingly, the test wafer analysis process should be repeated for each layer individually.

Once the above described preparation has been completed, the etch rate and depth and/or endpoint in the etch process for any layer of a wafer from the analysed batch can be monitored. This is achieved by placing any of the wafers from the batch into the etching tool, and following the steps of the invention as explained previously with reference to FIGS. 8 and 9.

It will be appreciated that the method and apparatus of the present invention can be used in Capacitive Coupled Plasma (CCP) tools, Transformer Coupled Plasma (TCP) tools and any other variation of these. It could also be used with any other plasma source driven by radio-frequency (RF) for the purpose of plasma etching/processing a substrate, surface or wafer.

This technique could also be used in combination with other sensors such as conventional optical emission, downstream plasma monitoring, RF current, voltage or power.

The embodiments in the invention described with reference to the drawings comprise a computer apparatus and/or processes performed in a computer apparatus. However, the invention also extends to computer programs, particularly computer programs stored on or in a carrier adapted to bring the invention into practice. The program may be in the form of source code, object code, or a code intermediate source and object code, such as in partially compiled form or in any other form suitable for use in the implementation of the method according to the invention. The carrier may comprise a storage medium such as ROM, e.g. CD ROM, or magnetic recording medium, e.g. a floppy disk or hard disk. The carrier may be an electrical or optical signal which may be transmitted via an electrical or an optical cable or by radio or other means.

The invention is not limited to the embodiments hereinbefore described but may be varied in both construction and detail. The words “comprises/comprising” and the words “having/including” when used herein with reference to the present invention are used to specify the presence of stated features, integers, steps or components but does not preclude the presence or addition of one or more other features, integers, steps, components or groups thereof.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

1-80. (canceled)

81. A method for detecting at least one process parameter of a plasma etch process being performed on a semiconductor wafer, the method comprising the steps of:
detecting light being generated from the plasma during the etch process;
filtering the detected light to extract modulated light; and
processing the detected modulated light to determine at least one process parameter of the etch process.

82. The method of claim 81 wherein the process parameter is the endpoint or the etch rate of the etch process.

83. A method for detecting the etch rate of a plasma etch process being performed on a semiconductor wafer, the method comprising the steps of:
detecting light being generated from the plasma during the etch process;
filtering the detected light to extract modulated light; and
processing the detected modulated light to determine the etch rate of the etch process.

84. The method of claim 83, wherein the detecting further comprises the step of filtering the light to detect selected wavelength bands.

85. The method of claim 83, wherein the processing comprises the steps of:
converting the detected light into a digital signal;
transforming the digital signal into a frequency domain signal; extracting one or more pre-selected frequencies from the frequency domain signal for use as process monitor signals;
generating a plot proportional to the intensity of the process monitor signals over the elapsed time of the etch process; and
determining the etch rate from the plot.

86. The method of claim 85, wherein the step of generating a plot proportional to the intensity of the process monitor signals over the elapsed time of the etch process comprises:
calibrating the values of the process monitor signals so as to generate converted signal values; and
generating a plot of the converted signal values over the elapsed time of the etch process.

87. The method of claim 86 wherein the step of calibrating comprises the multiplication of a conversion constant to the values of the process monitor signals.

88. The method of claim 86, further comprising the step of integrating the plot so as to generate a second plot of etch area over elapsed time of the etch process, and determining the etch depth from the second plot.

89. The method of claim 88, further comprising the step of generating an indicator when a signal level transition in the second plot matches a stored value representing a target etch depth.

90. The method as claimed in any of claim 85, wherein the process monitor signals are determined during a test wafer analysis of wafers of the same batch as the wafer.

91. The method as claimed in any of claim 87, wherein the conversion constant is determined during a test wafer analysis of wafers of the same batch as the wafer.

92. The method of claim 90, wherein the test wafer analysis of the batch comprises the steps of:
detecting modulated light being generated from the plasma of a test wafer being etched over the duration of an etch process;
converting the detected modulated light into digital signals;
transforming the digital signals into frequency domain signals;
determining the main frequencies of the frequency domain signals; and
selecting those main frequencies which are sensitive to changes in the etch rate as the process monitor signals.

93. The method of claim 92, wherein the step of selecting those main frequencies which are sensitive to changes in the etch rate as the process monitor signals comprises the step of:
generating electron microscopy images of a set of test wafers over the etching process, measuring the etch rate and etch depth of the etch process as a function of time from the generated images; and
selecting those main frequencies which have values over time which correlate to the measured etch rate and etch depth as the process monitor signals.

94. The method of claim 93, further comprising the step of establishing the linear relationship between the values of the selected process monitor signals over time and the actual etch rate.

95. The method of claim 94, wherein the established linear relationship is stored as the conversion constant.

96. A method to determine the process monitor signals and conversion constant for use in a method of detecting the etch rate of a plasma etch process to be performed on a semiconductor wafer from a particular wafer batch, the method comprising the steps of:
placing a test wafer of the wafer batch in a plasma etching tool and initiating the etch process; detecting modulated light being generated from the plasma of the test wafer over the duration of the etch process;
converting the detected modulated light into digital signals;
transforming the digital signals into frequency domain signals;
determining the main frequencies of the frequency domain signals;
selecting those main frequencies which are sensitive to changes in the etch rate as the process monitor signals;
establishing the linear relationship between the values of the selected process monitor signals over time and the actual etch rate; and
storing the established linear relationship as the conversion constant.

97. An apparatus for determining the process monitor signals and conversion constant for use in detecting the etch rate of a plasma etch process to be performed on a semiconductor wafer from a particular wafer batch, comprising:
a plasma etching tool;
a means for detecting modulated light being generated from the plasma of the test wafer over the duration of the etch process;
a means for converting the detected modulated light into digital signals;
a means for transforming the digital signals into frequency domain signals;
a means for determining the main frequencies of the frequency domain signals;
a means for selecting those main frequencies which are sensitive to changes in the etch rate as the process monitor signals; a means for establishing the linear relationship between the values of the selected process monitor signals over time and the actual etch rate; and
a means for storing the established linear relationship as the conversion constant.

98. A data storage medium having a set of machine-executable instructions that describes the method for detecting at least one process parameter of a plasma etch process being performed on a semiconductor wafer according to claim 81.

99. A data storage medium having a set of machine-executable instructions that describes the method for detecting the etch rate of a plasma etch process being performed on a semiconductor wafer being performed on a semiconductor wafer according to claim 83.

100. A data storage medium having a set of machine-executable instructions that describes the method to determine the process monitor signals and conversion constant for use in a method of detecting the etch rate of a plasma etch process to be performed on a semiconductor wafer from a particular wafer batch according to claim 96.

101. A method for detecting the endpoint of a plasma etch process being performed on a semiconductor wafer, the method comprising the steps of:
detecting light being generated from the plasma;
filtering the detected light to extract modulated light;
processing the detected modulated light to determine when the endpoint of the etch process has been reached; and
generating an indicator when the endpoint has been determined.

102. The method as claimed in claim 101, wherein the detecting further comprises the step of filtering the light to detect selected wavelength bands.

103. The method as claimed in claim 101, wherein the processing comprises performing an endpoint detection algorithm on the detected modulated light.

104. The method as claimed in claim 103, wherein the endpoint detection algorithm comprises the steps of:
converting the detected light into a digital signal;
transforming the digital signal into a frequency domain signal;
determining whether a signal level transition of one or more pre-selected frequencies matches a stored signal level transition value which corresponds to when the endpoint in the etch process is reached.

105. The method as claimed in claim 104, wherein the step of determining whether a signal level transition of one or more pre-selected frequencies matches a stored signal level transition value comprises the steps of:
extracting the one or more pre-selected frequencies from the frequency domain signal for use as process monitor signals;
generating a plot of the intensity of the process monitor signals over the elapsed time of the etch process; and
determining whether a signal level transition in the plot matches a stored signal level transition value.

106. The method as claimed in any of claim 104, wherein the stored signal level transition value and the process monitor signals are determined during a test wafer analysis of wafers of the same batch as the wafer.

107. The method of claim 106, wherein the test wafer analysis of the batch comprises the steps of:
detecting modulated light being generated from the plasma of a test wafer being etched over the duration of the etch process;
converting the detected modulated light signals into digital signals;
transforming the digital signals into frequency domain signals;
determining the main frequencies of the frequency domain signals;
selecting those main frequencies which exhibit a signal level transition when the endpoint of the etch process is reached as the process monitor signals; and
storing the value of this signal level transition for use as the stored signal level transition value.

108. The method of claim 107 wherein the step of selecting those main frequencies which exhibit a signal level transition when the endpoint of the etch process is reached as the process monitor signals comprises the step of generating a plot of the intensity of the main frequencies over the duration of the time of the etch process; and selecting those main frequencies which exhibit in the plot a signal level transition when the endpoint of the etch process is reached as the process monitor signals.

109. The method of any of claim 107, further comprising the step of:
generating electron microscopy images of the test wafer; and
wherein the step of selecting further comprises selecting those main frequencies which exhibit in the plot a signal level transition when the test wafer images show that the endpoint of the etch process is reached as the process monitor signals.

110. A method to determine the process monitor signals and a signal level transition value for use in a method of detecting the endpoint of a plasma etch process to be performed on a semiconductor wafer from a particular wafer batch, the method comprising the steps of:
placing a test wafer of the wafer batch in a plasma etching tool and initiating the etch process; detecting modulated light being generated from the plasma of the test wafer over the duration of the etch process;
converting the detected modulated light signals into digital signals;
transforming the digital signals into frequency domain signals;
determining the main frequencies of the frequency domain signals;
generating a plot of the intensity of the main frequencies over the duration of the time of the etch process;
selecting those main frequencies which exhibit in the plot a signal level transition when the endpoint of the etch process is reached as the process monitor signals; and
selecting the value of this signal level transition as the signal level transition value to be stored.

111. The method of any of claim 110, further comprising the step of:
generating electron microscopy images of the test wafer; and
wherein the step of selecting further comprises selecting those main frequencies which exhibit in the plot a signal level transition when the test wafer images show that the endpoint of the etch process is reached as the process monitor signals.

112. An apparatus for detecting the endpoint of a plasma etch process to be performed on a semiconductor wafer, comprising:
a plasma etching tool;
means for detecting light to be generated from the plasma during an etch process;
means for filtering the detected light to extract modulated light;
means for processing the detected modulated light to determine when the endpoint of the etch process has been reached; and
means for generating an indicator when the endpoint has been determined.

113. An apparatus for determining the process monitor signals and the signal level transition value to be stored for use in detecting the endpoint of a plasma etch process to be performed on a semiconductor wafer from a particular wafer batch, comprising:
a plasma etching tool;
a means for detecting modulated light to be generated from the plasma of a test wafer of the wafer batch over the duration of an etch process;
a means for converting the detected modulated light signals into digital signals;
a means for transforming the digital signals into frequency domain signals;
a means for determining the main frequencies of the frequency domain signals;
a means for selecting those main frequencies which exhibit a signal level transition when the endpoint of the etch process is reached as the process monitor signals; and
a means for selecting the value of this signal level transition as the signal level transition value.

114. A data storage medium having a set of machine-executable instructions that describes the method of detecting the endpoint of a plasma etch process being performed on a semiconductor wafer according to claim 101.

115. A data storage medium having a set of machine-executable instructions that describes the method to determine the process monitor signals and a signal level transition value for use in a method of detecting the endpoint of a plasma etch process to be performed on a semiconductor wafer from a particular wafer batch according to claim 110.
